(19) United States
(12) Patent Application Publication
(10) Pub. No.: US 2024/0020446 A1
(43) Pub. Date: Jan. 18, 2024

(54) USING COLLABORATIVE CONVERSATIONAL AGENTS AND METRIC PREDICTION TO PERFORM PROMPT-BASED PHYSICAL CIRCUIT DESIGN

(71) Applicant: Intel Corporation, Santa Clara, CA (US)

(72) Inventors: Siddhartha Nath, Danville, CA (US); Rajeshkumar Sambandam, Santa Clara, CA (US); Uday Mallappa, Sunnyvale, CA (US); Somdeb Majumdar, Mission Viejo, CA (US); Mariano Phielipp, Mesa, AZ (US); Xia Zhu, Portland, OR (US); Jianfang Olena Zhu, Portland, OR (US); Francisco Javier Vera Rivera, Barcelona (ES); Miaomiao Ma, Sunnyvale, CA (US)

(21) Appl. No.: 18/477,844

(22) Filed: Sep. 29, 2023

Related U.S. Application Data
(60) Provisional application No. 63/513,677, filed on Jul. 14, 2023.

(51) Int. Cl. G06F 30/31; G06N 3/084

(52) U.S. Cl. CPC G06F 30/31; G06N 3/084

(57) ABSTRACT

Systems, apparatuses and methods may provide for technology that determines a vocabulary based on EDA tool terminologies and/or a natural language, queries and recommends, by a plurality of virtual agents, actions based on a design state and the vocabulary, wherein the plurality of agents is to include a tool agent and a designer agent, and executes a set of modifications to the design state in accordance with a collaboration between the plurality of agents. The technology may also convert a first user query from a first format to a second format, wherein the first format is incompatible with a trained AI model of a hardware architecture and the second format is compatible with the trained AI model, generate one or more predictions from the trained AI model based on the converted first user query, and select a subset of recommendations from a set of candidate architectures based on the prediction(s).

### CROSS-REFERENCE TO RELATED APPLICATIONS

The present application claims the benefit of priority to U.S. Provisional Patent Application No. 63/513,677 filed on Jul. 14, 2023.

### TECHNICAL FIELD

Embodiments generally relate to circuit design. More particularly, embodiments relate to using collaborative conversational agents and metric prediction to perform prompt-based physical circuit design.

### BACKGROUND

During the early phases of integrated circuit (IC) product execution, architects and planners evaluate several high-level options and features. While accuracy is important, turnaround time may also be critical in order to explore as many options as possible. One issue that is common to most traditional design methods is that there are multiple versions of models and silicon data, and identifying the best version can be extremely difficult. Often, redundant experiments are executed because there is a lack of knowledge that data is already present.

More particularly, the backend physical design process in any IC design flow typically involves a set of collaterals (e.g., design database, libraries, electrical and geometrical constraints, tool knobs, quality of results (QoR) optimization strategies for power, performance, area, and cost (PPAC)) and a commercial electronic design automation (EDA) tool (e.g., FUSIONCOMPILER from SYNOPSYS or INNOVUS from CADENCE) that use the collaterals to perform optimization from synthesis (e.g., tech mapping, logic optimization) to place-and-route to signoff. During each stage of the flow (e.g., synthesis, floorplanning, placement, cloud testing service (CTS), routing and signoff) both the collaterals and the optimization trajectories change.

Typically, the designer analyzes the PPAC metrics at the end of each stage. When some metrics do not meet the requirements, the designer changes parts of the collaterals (e.g., constraints or tool knobs or QoR strategy) and reruns either from the same stage or from an earlier stage. The debug that the designer performs treats the EDA tool largely like a “black box”. Therefore, the expertise of the designer decides the extent of collateral changes and whether the PPAC metrics are better than the previous run iterations. This notion of treating the tool as a black box and conducting full reruns of a stage is expensive with respect to turnaround time (TAT) and does not guarantee PPAC improvements.

Thus, even when expert designers (e.g., design engineers or computer aided design/CAD methodology engineers) are involved, long TAT may be incurred due to the performance of complete runs of tool commands/stages when any collaterals change. Furthermore, there is no guarantee of PPAC improvements.

### BRIEF DESCRIPTION OF THE DRAWINGS

The various advantages of the embodiments will become apparent to one skilled in the art by reading the following specification and appended claims, and by referencing the following drawings, in which:

FIG. 1A is an illustration of an example of a collaborative agent flow according to an embodiment;

FIG. 1B is an illustration of an example of a recipe according to an embodiment;

FIG. 1C is an illustration of an example of a tool algorithm according to an embodiment;

FIG. 2 is an illustration of an example of a training of a tool agent according to an embodiment;

FIG. 3 is an illustration of an example of a training of a designer agent according to an embodiment;

FIG. 4 is an illustration of an example of a collaborative conversation between a plurality of virtual agents according to an embodiment;

FIG. 5 is a flowchart of an example of a method of operating a performance-enhanced computing system according to an embodiment;

FIG. 6 is a flowchart of an example of a metric prediction based auto-design guidance (MPADG) method according to an embodiment;

FIG. 7 is a flowchart of an example of a method of conducting inferences with an artificial intelligence (AI) model according to an embodiment;

FIG. 8 is a flowchart of an example of another method of operating a performance-enhanced computing system according to an embodiment;

FIG. 9 is a flowchart of an example of a method of converting a user query from a first format to a second format according to an embodiment;

FIG. 10 is a flowchart of an example of a method of correcting speech-to-text recognition results according to an embodiment;

FIGS. 11A and 11B are a flowchart of an example of a method of training an AI model according to an embodiment;

FIG. 12 is a block diagram of an example of a performance-enhanced computing system according to an embodiment;

FIG. 13 is an illustration of an example of a semiconductor package apparatus according to an embodiment;

FIG. 14 is a block diagram of an example of a processor according to an embodiment; and

FIG. 15 is a block diagram of an example of a multi-processor based computing system according to an embodiment.

### DETAILED DESCRIPTION

Collaborative Conversational Agents

The technology described herein overcomes the notion of treating an electronic design automation (EDA) tool as a black box and proposes a collaborative “conversation” between the designer and the tool, modeled as two virtual artificial intelligence (AI) agents. The technology also leverages prompt-based exchange of messages to adaptively modify the runs to achieve the best possible power, performance, area, and cost (PPAC) in one “shot” (e.g., single-pass/iteration). The PPAC improvement, if achievable, is guaranteed because the tool agent provides useful feedback to the designer agent to modify/relax collaterals. The technology described herein also provides a prompt-based engineering of the physical design flow.

In addition, EDA tools currently may not be able to disclose internal workings of their respective algorithms to designers (e.g., from a different company). Embodiments overcome this limitation because the tool agent only communicates what changes in collaterals can help with PPAC closure, and the designer agent can only select actions (e.g., changes to collaterals) that are “essential” (e.g., no waivers, or no in-house solutions are available) such that the tool can improve PPAC.

The technology described herein includes three main components.
(i) Determine vocabulary based on terminologies used in EDA tools for the two agents to communicate. This approach also involves developing appropriate application programming interfaces (APIs) for the agents to initialize, converse and terminate a session.
(ii) Train each virtual agent to recommend actions based on design state and prompt vocabulary.
(iii) One-shot PPAC closure from agent collaboration.

The technology described herein proposes an enhanced way to design chips using commercial EDA tools. There is also a significant saving in the effort of the designer and overall turnaround time (TAT) to achieve PPAC closure. Embodiments can be extended for any two pieces of software that originate from different entities and require working collaboratively to achieve a common objective. Embodiments may also use APIs and/or prompt-based messaging in which the designer and tool communicate to achieve the best PPAC.

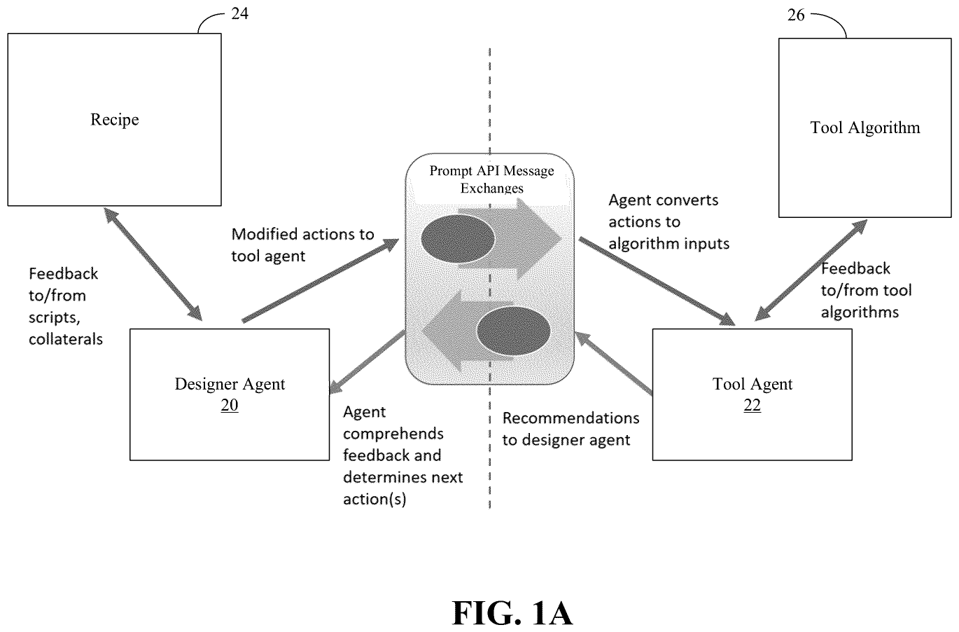

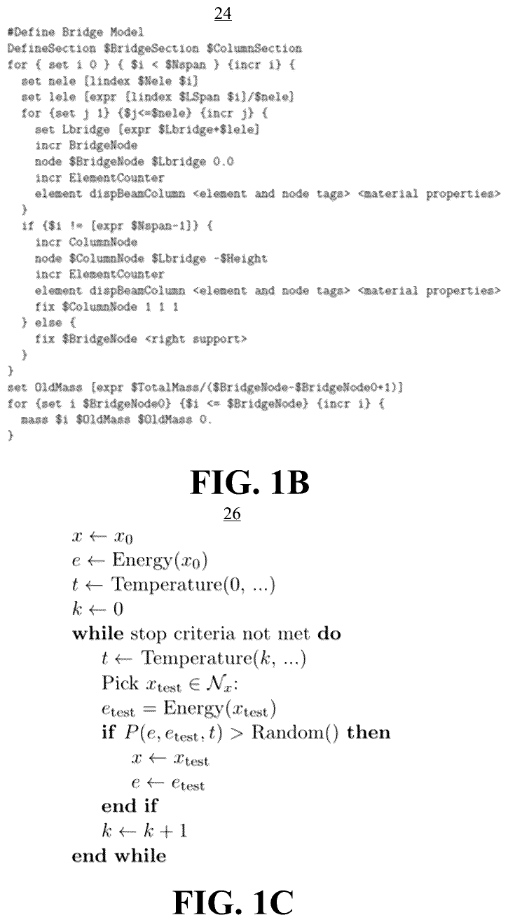

Turning now to FIGS. 1A-1C, an overall flow of the technology described herein is shown. The flow includes three key components, wherein the last component (iii) is an end-to-end flow for the best PPAC closure.

(i) Development of Vocabulary.

Embodiments propose a conversational AI prompt-based system to perform physical design flow for PPAC closure. A designer agent 20 and a tool agent 22 (collectively, conversational AI-based virtual agents) use a common vocabulary to exchange messages via prompts. The technology described herein uses an “EDA language”, which is a combination of the English language, Arabic (e.g., natural languages), Greek numerals, mathematical symbols and EDA-specific terminologies to comprise the union of a vocabulary. As part of training, this vocabulary may evolve based on the N-gram language that the training model uses. Examples of EDA-specific terminologies include “slack, timing, slew, cap, EM (electromigration), violation, constraint, relax, logic cone, transitive cone, fanin, fanout, etc.”

The virtual agents 20, 22 communicate with one another using the developed vocabulary. An example is as follows.
Tool agent 22 recommendation: Unable to reduce slack on endpoints {ep1, ep2, ep3} in scenario s1 by buffering owing to tight density constraint.
Designer agent 20 response: Relax density constraint in 5 um×5 um region around top-3 critical paths to {ep1, ep2, ep3} by 10% and retry buffering. Also, try sizing.
Tool agent response: Good news! Slack on ep1, ep2, ep3 reduced by 2 ps (picoseconds), 1.5 ps, 1.4 ps, respectively. Design TNS (total negative slack) improved by 4 ps.

(ii) Agent Training.

Each virtual agent 20, 22 may be trained separately using real as well as synthetic design information. A synthetic data generator is moderated either by using human expert feedback and/or by using models such as GAN (generative adversarial network), diffusion, etc. As will be discussed in greater detail, the designer agent 20 exchanges feedback with a “recipe” (e.g., scripts, collaterals) and the tool agent 22 exchanges feedback with a tool procedure/algorithm 26.

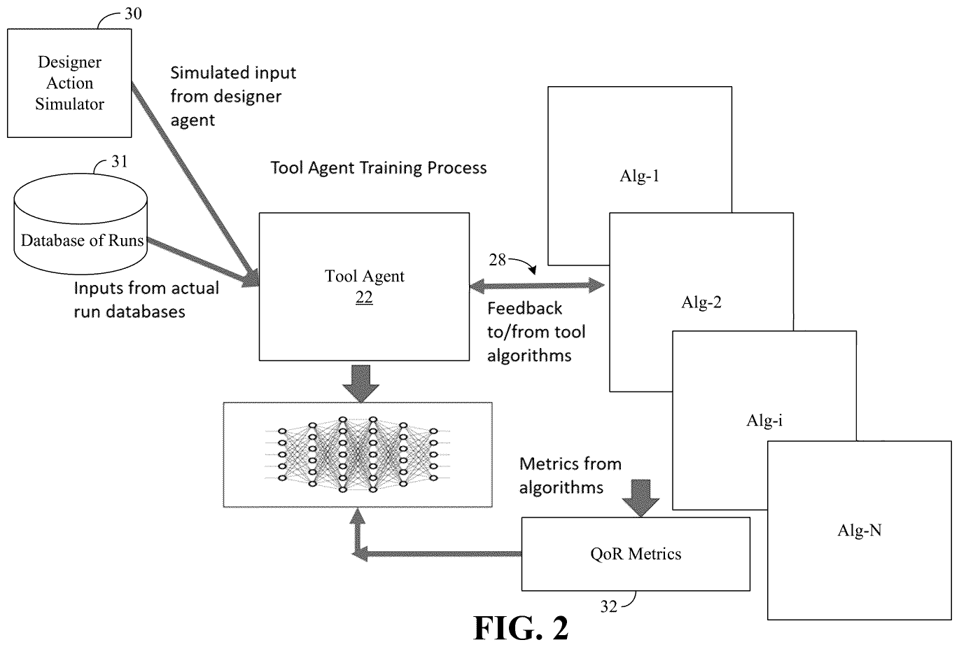

FIG. 2 illustrates the training process of the tool agent 22. Core procedures provide meaningful feedback 28 to the tool agent 22 as to why a certain optimization cannot improve PPAC metrics. For example, buffers cannot be added due to density issues, transition violation cannot be fixed by buffering due to blockage, or sufficient library cells are unavailable. The feedback 28 from procedures within the tool enable the tool agent 22 to formulate messages that the tool agent communicates with the designer agent. A designer action simulator 30 is a synthetic generator of messages by the designer agent. The illustrated tool agent 22 also received inputs from actual runs of a database 31. Network weights of the tool agent 22 are adjusted based on PPAC Quality of Results (QoR) metrics 32 observed when the tool agent 22 uses the messages from the designer agent and the database 31 run inputs to modify inputs to the tool procedures, and the procedures realize the PPAC metrics.

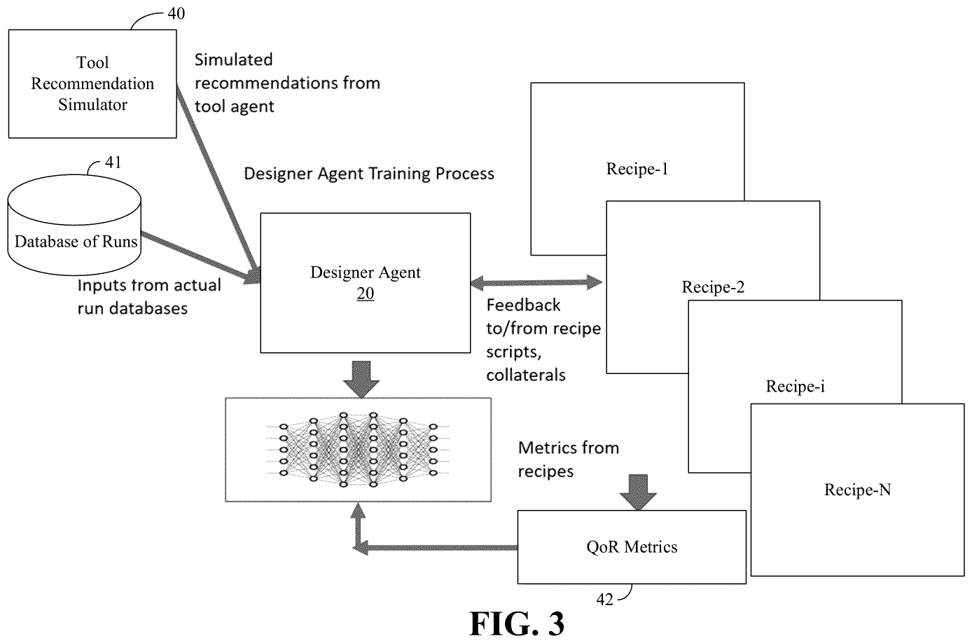

FIG. 3 illustrates the training process of the designer agent 20. A tool recommendation simulator 40 generates synthetic recommendations. The designer agent uses script recipes (e.g., “Recipe-1” through “Recipe-N”) and collaterals to determine responses to the recommendations received from the tool agent. The illustrated designer agent 20 also receives inputs from actual runs of a database 41. The responses are used to run the tool and obtain PPAC metrics 42, which are backpropagated to adjust the weights of a neural network in the designer agent 20.

(iii) End-to-End PPAC Closure Flow.

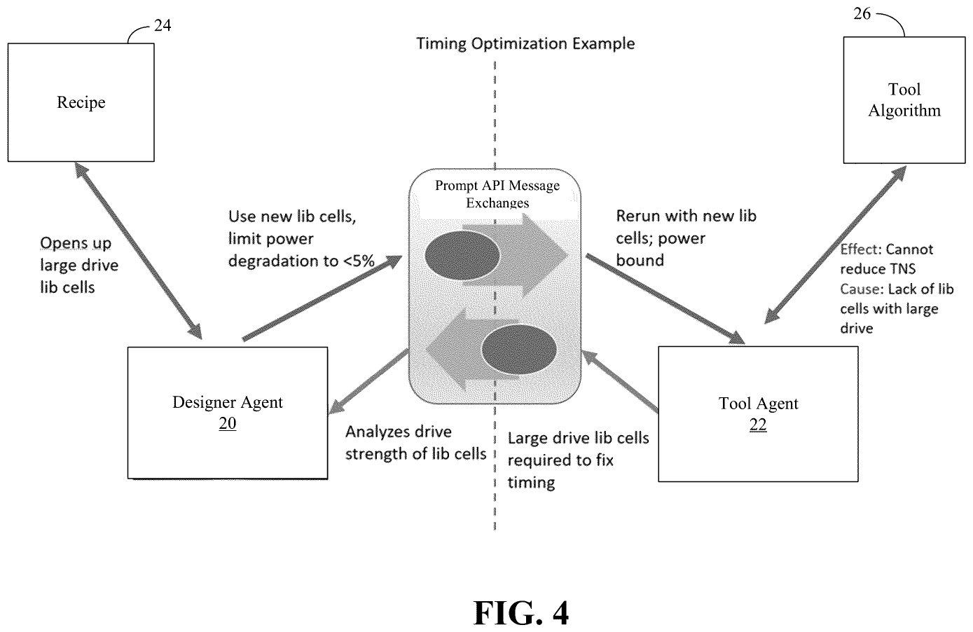

Turning now to FIG. 4, the trained tool agent 22 and the trained designer agent are used to collaborate and converse using the EDA language such that the best PPAC metrics are obtained for the design of the hardware architecture (e.g., IC). In the illustrated example, the virtual agents 20, 22 collaborate to achieve better timing optimization by using high drive-strength library (“lib”) cells (e.g., cells having a relatively strong capability to charge/discharge capacitances present at the output).

The virtual agents 20, 22 can begin collaborating from any part of the flow and the best achievable PPAC is expected from the moment the virtual agents 20, 22 converse. The virtual agents 20, 22 start conversing on-demand. For example, when an optimization tool algorithm 26 is unable to make progress in PPAC metrics, then the procedure can inform the tool agent 22. The tool agent 22 then activates (e.g., “wakes up”) and converses with the designer agent 20. In another instance, if the designer agent 20 observes that the runtime for a specific command is longer than anticipated, then the designer agent 20 can wake up the tool agent 22 to query why the runtime is large.

Below are some instances of and end-to-end PPAC closure with the tool agent 22 (e.g., tool AI agent/TAA) and designer agent 20 (e.g., designer AI agent/DAA).

### Example I: Timing Optimization

TAA query: Unable to reduce slack on pathgroup p1 due to lack of high drive lib cells. Can new lib cells be provided?

DAA response: Add new list of lib cells and retry.

TAA response: Good news! TNS on pathgroup p1 reduced by 30 ps.

### Example II: Power Optimization

TAA query: Cannot reduce internal power on cells $cellList and switching power on nets $netList any further due to timing and max transition constraints. Should the flow proceed?

DAA response: Try to tradeoff timing by 5% on logic cones formed by $cellList and retry.

TAA response: Still not possible.

DAA response: Only trade off on logic cones formed by $netList-1 by 5% and retry.

TAA response: Good news! Power reduced by 1% and design TNS degraded by 4.6%, no impact to max transition violations.

### Example III: Runtime Optimization

DAA query: Why is runtime for command $cmd over 3 hrs?

TAA response: There are too many paths with conflicting setup and hold constraints is causing multiple optimization loops of setup and hold, which is why runtime is larger than 3 hrs.

DAA response: Disable hold analysis on all scenarios except scenario s4 and proceed from current point.

TAA response: The optimization has completed timing (setup and hold) optimization and has now progressed to legalization.

DAA response: OK, use these scenarios settings and retry command $cmd. Alert me if runtime exceeds 3 hrs in timing optimization.

TAA response: OK, restarted command $cmd. Will inform if runtime of setup and hold exceeds 3 hrs.

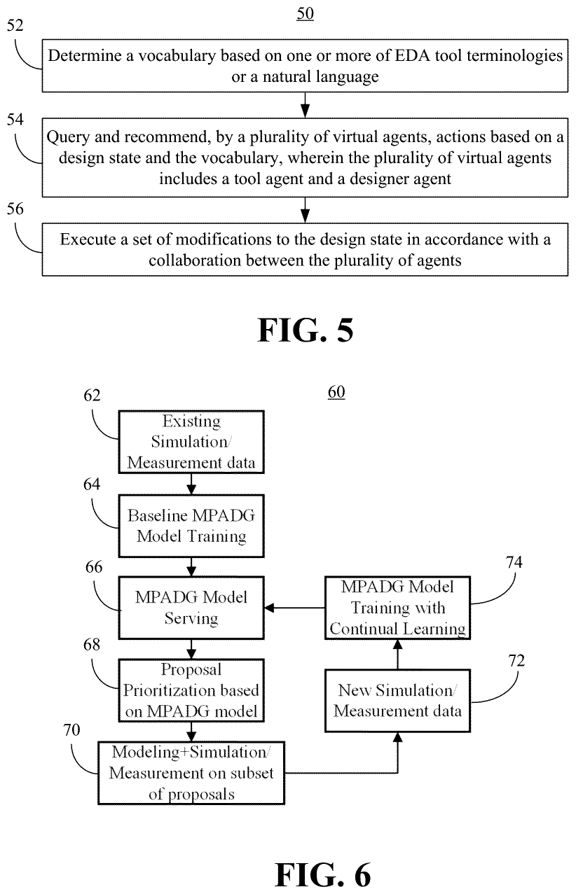

FIG. 5 shows a method 50 of operating a performance-enhanced computing system. The method 50 may be implemented in one or more modules as a set of logic instructions (e.g., executable program instructions) stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Computer program code to carry out operations shown in the method 50 can be written in any combination of one or more programming languages, including an object oriented programming language such as JAVA, SMALLTALK, C++ or the like and conventional procedural programming languages, such as the “C” programming language or similar programming languages. Additionally, logic instructions might include assembler instructions, instruction set architecture (ISA) instructions, machine instructions, machine dependent instructions, microcode, state-setting data, configuration data for integrated circuitry, state information that personalizes electronic circuitry and/or other structural components that are native to hardware (e.g., host processor, central processing unit/CPU, microcontroller, etc.).

Illustrated processing block 52 provides for determining a vocabulary based on one or more of EDA tool terminologies or a natural language (e.g., English, Arabic). Block 54 queries and recommends, by a plurality of virtual agents, actions based on a design state and the vocabulary, wherein the plurality of virtual agents includes a tool agent and a designer agent. In one example, block 54 trains the designer agent to query the design state and issue the recommended actions based on the design state. Additionally, block 54 may train the tool agent to report the design state and issue the recommended actions for actionable design based on the design state. Block 56 executes a set of modifications to the design state in accordance with a collaboration between the plurality of virtual agents. Thus, block 56 might result in a timing, power and/or runtime optimization in the hardware architecture. In an embodiment, the modifications to the design state result in a single-pass PPAC closure. The method 50 therefore enhances performance at least to the extent that using the collaboration between the virtual agents to modify the design state reduces effort on the part of the designer and/or shortens turnaround time to achieve the PPAC closure. The method 50 can also be extended for any two pieces of software originating from different entities (e.g., companies) working collaboratively with one another.

Metric Prediction

The technology described herein also uses an AI-based metric predictor (e.g., performance, power, and area, etc.) to determine whether proposed options/features would result in performance/power/area improvement and recommend top proposals for further consideration. Therefore, the technology dramatically reduces the resources and time needed to evaluate and develop new features.

Embodiments learn and update a knowledge base with architectural simulation and/or measurement data by using AI modeling. The trained AI model (e.g., neural network and/or regression model) can be used to predict important metrics (e.g., instructions per cycle/IPC, workload execution time, cache miss rate, dynamic power, area etc.) of different proposals. The trained AI model can also prioritize the proposals, which can guide architects to focus efforts on the most valuable subset of proposals.

More particularly, the technology described herein can evaluate new proposals in seconds, which substantially reduces the resources and time consumed for product planning and/or performance optimization. The technology can also learn insights from different types of existing data (e.g., simulations, measurements etc.) and generalize the knowledge from a single parameter change to multiple parameter changes, as well as the different combinations of parameters changes (e.g., memory technology, frequencies, cache sizes, processor architecture). Moreover, the technology facilitates efficient triage of architectural proposals and guides the architect to focus on the most valuable subset of proposals. In addition, the technology described herein substantially reduces prediction error rate compared to analytical model methods. Additionally, the technology described herein makes efficient use of existing simulation/measurement data and significantly reduces the evaluation time from days/months to seconds.

Turning now to FIG. 6, a metric prediction based auto-design guidance (MPADG) method 60 is shown. The method 60 may be implemented in one or more modules as a set of logic instructions stored in a machine- or computer-readable storage medium such as RAM, ROM, PROM, firmware, flash memory, etc., in hardware, or any combination thereof.

Illustrated processing block 64 leverages existing simulation and/or measurement data 62 to train a baseline MPADG model. Once the MPADG model is trained with a targeted accuracy, block 66 hosts the trained model in a cloud computing infrastructure for MPADG service. At the same time, the trained model can be distributed to architects. When architects propose M number of new features, all proposals are run through AI inference with the trained MPADG model to predict the performance/power/area impact. Further, block 68 recommends the top N (N<<M) proposals that demonstrate the most promising results as the prioritized features for the product (e.g., hardware architecture, IC). Block 70 conducts a detailed and more time-consuming modeling and simulation/measurement only on the selected proposals.

Once new simulation/measurement data 72 becomes available, block 74 leverages the new data to further train MPADG model in a continuous learning manner. Overall, the method 60 creates a positive feedback loop—the trained MPADG model provides guidance for selecting new product features and the simulation and/or measurement on selected feature further helps improve the quality of MPADG model. MPADG model continues to update and gain insights whenever the new simulation/measurement data 72 becomes available.

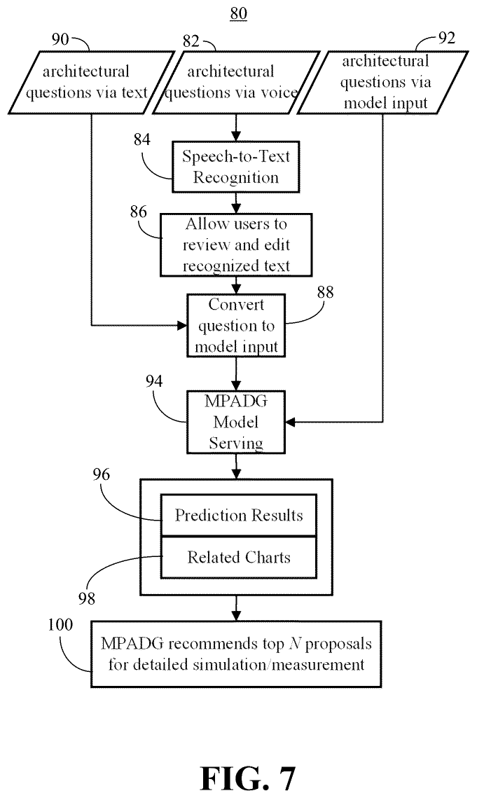

FIG. 7 shows a method 80 of conducting inferences with an AI model (e.g., MPADG model). The method 80 may generally be incorporated into block 66 and/or block 68 (FIG. 6), already discussed. More particularly, the method 80 may be implemented in one or more modules as a set of logic instructions stored in a machine- or computer-readable storage medium such as RAM, ROM, PROM, firmware, flash memory, etc., in hardware, or any combination thereof.

In general, once the MPADG model is trained, the MPADG model is hosted as a service to architects and/or directly released to architects. When architects propose new features, the architects can obtain the predicted performance by asking questions to the MPADG model via voice, text, or directly provide model input.

If the question/query is asked by voice input 82 (e.g., a format that is incompatible with the MPADG model), then an AI-based speech-to-text/automatic speech recognition (ASR) 84 is used to automatically recognize the voice input 82 and convert the voice input 82 to text. For example, the voice input 82 might be “what's the impact of changing from DDR5 to LPDDR5?”. Since the ASR 84 may encounter difficulties based on different accents, block 86 displays the converted text to users, so that the architects can review, and further update the converted text. The validated text for the question is then converted in block 88 to model input via a natural language processing (NLP) model. If the question is asked by text input 90 (e.g., a format that is incompatible with the MPADG model), then the text input 90 is converted in block 88 to model input using the NLP model. If model input 92 (e.g., a format that is compatible with the MPADG model) is provided by users, then the model input 92 can be directly applied to the MPADG model to run inferences in block 94. After the MPADG model makes inferences, predicted results 96, along with one or more corresponding charts 98 for the asked question, are returned to users. Based on the prediction results 96, the MPADG model “sweeps” multiple M configurations and recommends the top N most valuable proposals in block 100. The detailed, time-consuming modeling and simulation/measurement are reduced to a small subset of total proposals (N<<M). Whenever there is an updated MPADG model available, the service is updated with the new model accordingly.

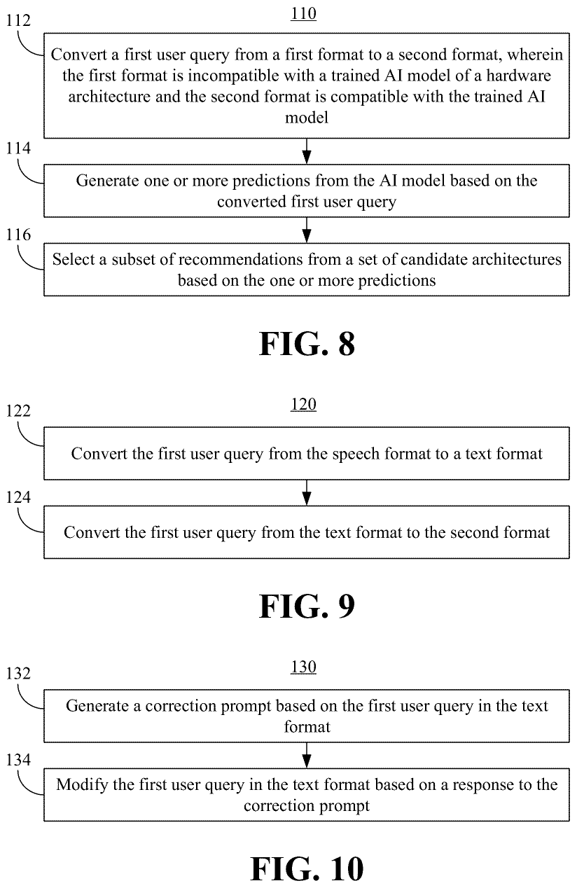

FIG. 8 shows another method 110 of operating a performance-enhanced computing system. The method 110 may be implemented in one or more modules as a set of logic instructions stored in a machine- or computer-readable storage medium such as RAM, ROM, PROM, firmware, flash memory, etc., in hardware, or any combination thereof.

Illustrated processing block 112 provides for converting a first user query from a first format to a second format, wherein the first format is incompatible with a trained AI model (e.g., MPADG model) of a hardware architecture and the second format is compatible with the trained AI model. In one example, the first format is a text format. In another example, the first format is a speech (e.g., voice) format. Block 114 generates one or more predictions from the AI model based on the converted first user query. In an embodiment, block 114 generates the prediction(s) further based on a second user query, wherein the second user query is in the second format. Block 116 selects a subset of recommendations from a set of candidate architectures based on the prediction(s). In one example, block 116 outputs the set of candidate architectures via a user interface device (e.g., display) and/or a network controller.

The method 110 therefore enhances performance at least to the extent that selecting the subset of recommendations based on predictions from the AI model enables new proposals to be evaluated in seconds, which substantially reduces the resources and time consumed for product planning and/or performance optimization. The method 110 can also learn insights from different types of existing data (e.g., simulations, measurements etc.) and generalize the knowledge from a single parameter change to multiple parameter changes, as well as the different combinations of parameters changes (e.g., memory technology, frequencies, cache sizes, processor architecture). Moreover, the method 110 facilitates efficient triage of architectural proposals and guides the architect to focus on the most valuable subset of proposals. In addition, the method 110 substantially reduces prediction error rate compared to analytical model methods. Additionally, the method 110 makes efficient use of existing simulation/measurement data and significantly reduces the evaluation time from days/months to seconds.

FIG. 9 shows a method 120 of converting a user query from a first format to a second format. The method 120 may generally be incorporated into block 112 (FIG. 8), already discussed. More particularly, the method 120 may be implemented in one or more modules as a set of logic instructions stored in a machine- or computer-readable storage medium such as RAM, ROM, PROM, firmware, flash memory, etc., in hardware, or any combination thereof.

Illustrated processing block 122 provides for converting the first user query from the speech format to a text format (e.g., via ASR). Block 124 converts the first user query from the text format to the second format (e.g., which is compatible with the trained AI model).

FIG. 10 shows a method 130 of correcting speech-to-text recognition results. The method 130 may generally be incorporated into block 122 (FIG. 9), already discussed. More particularly, the method 120 may be implemented in one or more modules as a set of logic instructions stored in a machine- or computer-readable storage medium such as RAM, ROM, PROM, firmware, flash memory, etc., in hardware, or any combination thereof.

Illustrated processing block 132 provides for generating a correction prompt based on the first user query in the text format. Block 134 modifies the first user query in the text format based on a response to the correction prompt.

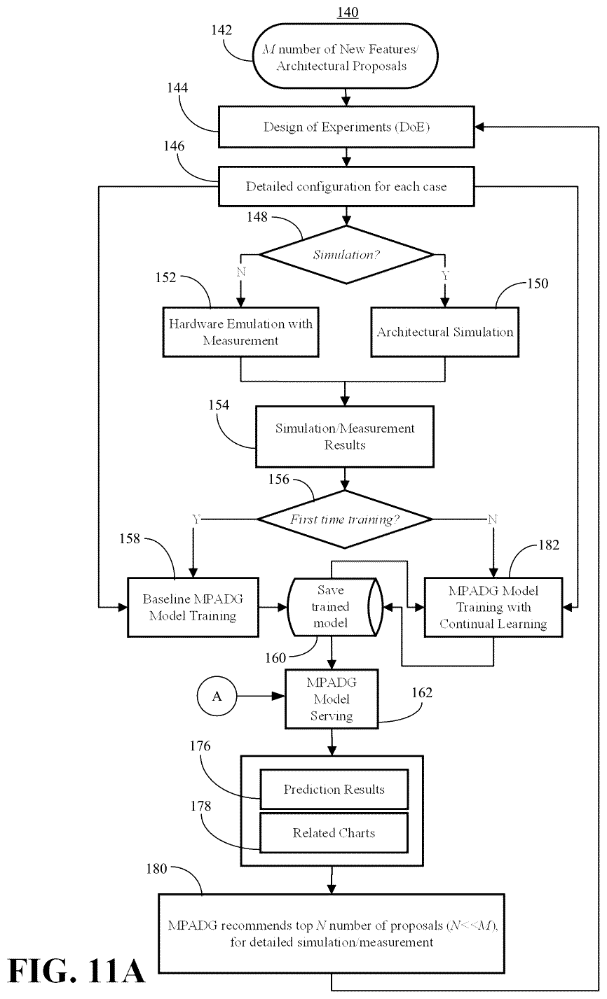

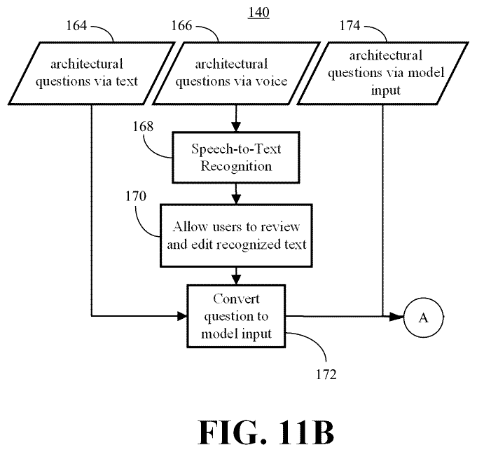

FIGS. 11A and 11B show a method 140 of training an AI model. The method 140 may be implemented at least partly in one or more modules as a set of logic instructions stored in a machine- or computer-readable storage medium such as RAM, ROM, PROM, firmware, flash memory, etc., in hardware, or any combination thereof.

In general, the method 140 receives M number of new features and/or architectural proposals 142 (e.g., set of candidate architectures). A design of experiments (DoE) is developed at block 144 and a detailed configuration is generated at block 146 for each case. Each experiment can have a corresponding configuration such as, for example, core frequency, uncore frequency, memory type, and memory latency etc. Sensitivity studies that sweep several parameters may also be run. During post-silicon stages, similar experiments are conducted and low-level data are collected through an event monitoring tool such as EMON. Moreover, both simulations and measurements can generate power/performance/area results.

A determination is made at block 148 as to whether architectural simulations are to be executed. If so, block 150 executes the architectural simulations. Otherwise, block 152 executes hardware emulations with measurements. Once the simulation and/or measurement results are obtained at block 154, a determination is made at block 156 as to whether the current iteration represents a first time training. If so, block 158 conducts a baseline training of the AI model based on the set of candidate architectures. In one example, the baseline training is conducted based on one or more of hardware emulation measurements, architectural simulation results or a plurality of different workloads associated with the set of candidate architectures. More particularly, the final power/performance/area results and the corresponding configurations that generate these power/performance/area values are used to train the baseline AI model. The objective of the AI model is to take the configurations as input, and predict corresponding performance/power/area results (e.g., instructions per cycle/IPC, total execution time, dynamic power, area, etc.). The trained model is saved to a repository 160 (e.g., knowledge base), wherein block 162 serves (e.g., deploys) the trained AI model.

As already noted, user queries may be received in various different formats. For example, if the user query is asked by a voice input 166 (e.g., a format that is incompatible with the trained AI model), then an AI-based ASR 168 is used to automatically recognize the voice input 166 and convert the voice input 166 to text. Since the ASR 168 may encounter difficulties based on different accents, block 170 displays the converted text to users, so that the architects can review, and further update the converted text. The validated text for the question is then converted in block 172 to model input via a natural language processing (NLP) model. If the question is asked by text input 164 (e.g., a format that is incompatible with the trained AI model), then the text input 164 is converted in block 172 to model input using the NLP model. If model input 174 (e.g., a format that is compatible with the trained AI model) is provided by users, then the model input 174 can be directly applied to the trained AI model to run inferences.

After the trained AI model makes inferences, predicted results 176, along with a corresponding chart 178 for the asked question, are returned to users. Based on the prediction results 176, the trained AI model recommends the top N most valuable proposals (e.g., subset of recommendations) in block 180. The detailed, time-consuming modeling and simulation/measurement are therefore reduced to a small subset of total proposals (N<<M). Whenever there is an updated trained AI model available, the service is updated with the new model accordingly. Thus, the method 140 returns to block 144 and if it is determined at block 156 that the current iteration is not the first time training, block 182 conducts a continual learning training of the AI model after the baseline training based on the subset of recommendations. In one example, the continual learning training is conducted further based on hardware emulation measurements, architectural simulation results and/or a plurality of different workloads associated with the subset of recommendations.

After the MPADG model guides the new feature/architectural proposal selection, the selected features go through a detailed simulation and/or measurement phase. The new simulation/measurement data is used to further improve the MPADG model. Architects can register data folders or database addresses to use for the new data. The MPADG model automatically detects new data availability and triggers model training when new data is available. This approach ensures that the trained MPADG model is always up to date with the latest available data and maintains high accuracy for design guidance.

To avoid catastrophic effect where a model may forget previous knowledge when new knowledge is learned, the data repository 160 is maintained to keep the most representative historical data and ensure that the MPADG model is always tested with the representative historical data. The historical data can be prioritized based on the pass rate and/or alignment score. The pass rate measures how many workload traces successfully pass the simulation, which is an indicator of the simulator quality. The alignment score is based on calibrations between simulation and measurement. Simulations are typically conducted before the physical hardware becomes available.

After the hardware is implemented and built, the measured data from the actual hardware can be used to calibrate the corresponding simulation results that were obtained before hardware was available. A higher alignment score indicates higher simulation quality. Only high quality historical data is maintained in the data repository 160 to ensure that the MPADG model is always tested with previously verified knowledge. Once a product is discontinued (e.g., “end of lifed”/“EoL'd”), corresponding data is gradually removed from the data repository to focus on the most relevant data.

In one example, the method 140 was used to predict the cache costs of different L2 (level two) and L3 (level three) cache size combinations. Compared to an analytical model, which assumes that as the cache size increases, the cache miss rate decreases following a square root relationship, the recommendations of the method 140 demonstrated substantially less error (e.g., mean absolute percentage error/MAPE) and substantially greater performance speedup.

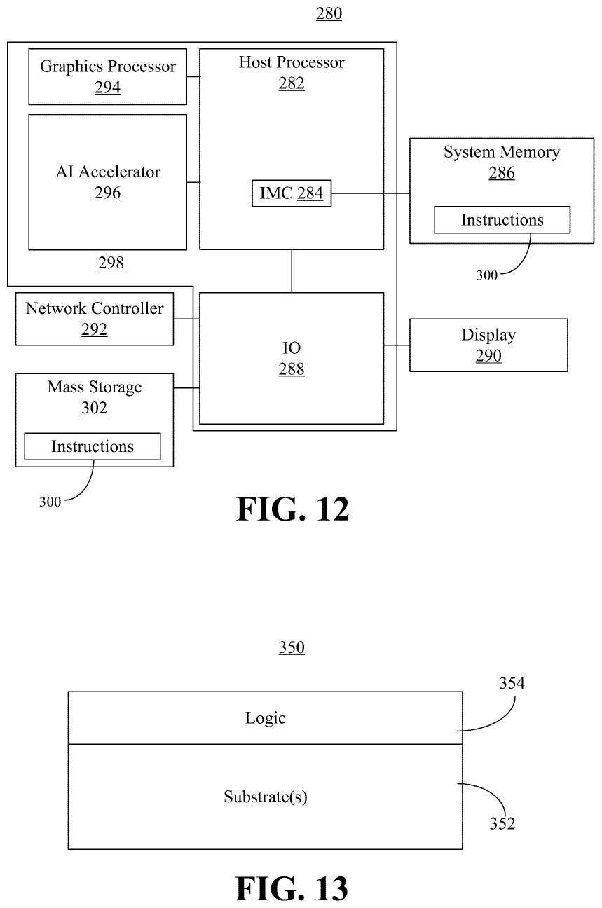

Turning now to FIG. 12, a performance-enhanced computing system 280 is shown. The system 280 may generally be part of an electronic device/platform having computing functionality (e.g., personal digital assistant/PDA, notebook computer, tablet computer, convertible tablet, edge node, server, cloud computing infrastructure), communications functionality (e.g., smart phone), imaging functionality (e.g., camera, camcorder), media playing functionality (e.g., smart television/TV), wearable functionality (e.g., watch, eyewear, headwear, footwear, jewelry), vehicular functionality (e.g., car, truck, motorcycle), robotic functionality (e.g., autonomous robot), Internet of Things (IoT) functionality, drone functionality, etc., or any combination thereof.

In the illustrated example, the system 280 includes a host processor 282 (e.g., central processing unit/CPU) having an integrated memory controller (IMC) 284 that is coupled to a system memory 286 (e.g., dual inline memory module/DIMM including a plurality of DRAMs). In an embodiment, an IO (input/output) module 288 is coupled to the host processor 282. The illustrated IO module 288 communicates with, for example, a display 290 (e.g., touch screen, liquid crystal display/LCD, light emitting diode/LED display), mass storage 302 (e.g., hard disk drive/HDD, optical disc, solid state drive/SSD) and a network controller 292 (e.g., wired and/or wireless). The host processor 282 may be combined with the IO module 288, a graphics processor 294, and an AI accelerator 296 (e.g., specialized processor) into a system on chip (SoC) 298.

In an embodiment, the AI accelerator 296 executes instructions 300 retrieved from the system memory 286 and/or the mass storage 302 to perform one or more aspects of the method 50 (FIG. 5), the method 60 (FIG. 6), the method 80 (FIG. 7), the method 110 (FIG. 8), the method 120 (FIG. 9), the method 130 (FIG. 10) and/or the method 140 (FIGS. 11A and 11B), already discussed. Thus, the AI accelerator 296 can execute the instructions 300 to determine a vocabulary based on one or more of electronic design automation (EDA) tool terminologies or a natural language, query and recommend, by a plurality of virtual agents, actions based on a design state and the vocabulary, wherein the plurality of virtual agents is to include a tool agent and a designer agent, and execute a set of modifications to the design state in accordance with a collaboration between the plurality of agents. The computing system 280 is therefore considered performance-enhanced at least to the extent that using the collaboration between the virtual agents to modify the design state reduces effort on the part of the designer and/or shortens turnaround time to achieve the PPAC closure. The computing system 280 can also be extended for any two pieces of software originating from different entities (e.g., companies) working collaboratively with one another.

The AI accelerator 296 can also execute the instructions 300 to convert a first user query from a first format to a second format, wherein the first format is incompatible with a trained AI model of a hardware architecture and the second format is compatible with the trained AI model, generate one or more predictions from the trained AI model based on the converted first user query, and select a subset of recommendations from a set of candidate architectures based on the one or more predictions.

The computing system 280 is therefore further considered performance-enhanced at least to the extent that selecting the subset of recommendations based on predictions from the AI model enables new proposals to be evaluated in seconds, which substantially reduces the resources and time consumed for product planning and/or performance optimization. The computing system 280 can also learn insights from different types of existing data (e.g., simulations, measurements etc.) and generalize the knowledge from a single parameter change to multiple parameter changes, as well as the different combinations of parameters changes (e.g., memory technology, frequencies, cache sizes, processor architecture). Moreover, the computing system 280 facilitates efficient triage of architectural proposals and guides the architect to focus on the most valuable subset of proposals. In addition, the computing system 280 substantially reduces prediction error rate compared to analytical model methods. Additionally, the computing system 280 makes efficient use of existing simulation/measurement data and significantly reduces the evaluation time from days/months to seconds.

FIG. 13 shows a semiconductor apparatus 350 (e.g., chip, die, package). The illustrated apparatus 350 includes one or more substrates 352 (e.g., silicon, sapphire, gallium arsenide) and logic 354 (e.g., transistor array and other integrated circuit/IC components) coupled to the substrate(s) 352. In an embodiment, the logic 354 implements one or more aspects of the method 50 (FIG. 5), the method 60 (FIG. 6), the method 80 (FIG. 7), the method 110 (FIG. 8), the method 120 (FIG. 9), the method 130 (FIG. 10) and/or the method 140 (FIGS. 11A and 11B), already discussed

The logic 354 may be implemented at least partly in configurable or fixed-functionality hardware. In one example, the logic 354 includes transistor channel regions that are positioned (e.g., embedded) within the substrate(s) 352. Thus, the interface between the logic 354 and the substrate(s) 352 may not be an abrupt junction. The logic 354 may also be considered to include an epitaxial layer that is grown on an initial wafer of the substrate(s) 352.

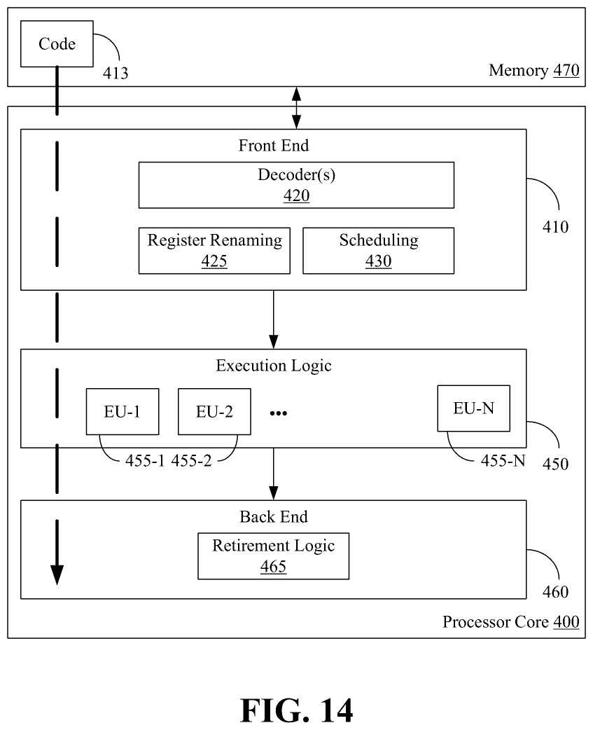

FIG. 14 illustrates a processor core 400 according to one embodiment. The processor core 400 may be the core for any type of processor, such as a micro-processor, an embedded processor, a digital signal processor (DSP), a network processor, or other device to execute code. Although only one processor core 400 is illustrated in FIG. 14, a processing element may alternatively include more than one of the processor core 400 illustrated in FIG. 14. The processor core 400 may be a single-threaded core or, for at least one embodiment, the processor core 400 may be multithreaded in that it may include more than one hardware thread context (or “logical processor”) per core.

FIG. 14 also illustrates a memory 470 coupled to the processor core 400. The memory 470 may be any of a wide variety of memories (including various layers of memory hierarchy) as are known or otherwise available to those of skill in the art. The memory 470 may include one or more code 413 instruction(s) to be executed by the processor core 400, wherein the code 413 may implement the method 50 (FIG. 5), the method 60 (FIG. 6), the method 80 (FIG. 7), the method 110 (FIG. 8), the method 120 (FIG. 9), the method 130 (FIG. 10) and/or the method 140 (FIGS. 11A and 11B), already discussed. The processor core 400 follows a program sequence of instructions indicated by the code 413. Each instruction may enter a front end portion 410 and be processed by one or more decoders 420. The decoder 420 may generate as its output a micro operation such as a fixed width micro operation in a predefined format, or may generate other instructions, microinstructions, or control signals which reflect the original code instruction. The illustrated front end portion 410 also includes register renaming logic 425 and scheduling logic 430, which generally allocate resources and queue the operation corresponding to the convert instruction for execution.

The processor core 400 is shown including execution logic 450 having a set of execution units 455-1 through 455-N. Some embodiments may include a number of execution units dedicated to specific functions or sets of functions. Other embodiments may include only one execution unit or one execution unit that can perform a particular function. The illustrated execution logic 450 performs the operations specified by code instructions.

After completion of execution of the operations specified by the code instructions, back end logic 460 retires the instructions of the code 413. In one embodiment, the processor core 400 allows out of order execution but requires in order retirement of instructions. Retirement logic 465 may take a variety of forms as known to those of skill in the art (e.g., re-order buffers or the like). In this manner, the processor core 400 is transformed during execution of the code 413, at least in terms of the output generated by the decoder, the hardware registers and tables utilized by the register renaming logic 425, and any registers (not shown) modified by the execution logic 450.

Although not illustrated in FIG. 14, a processing element may include other elements on chip with the processor core 400. For example, a processing element may include memory control logic along with the processor core 400. The processing element may include I/O control logic and/or may include I/O control logic integrated with memory control logic. The processing element may also include one or more caches.

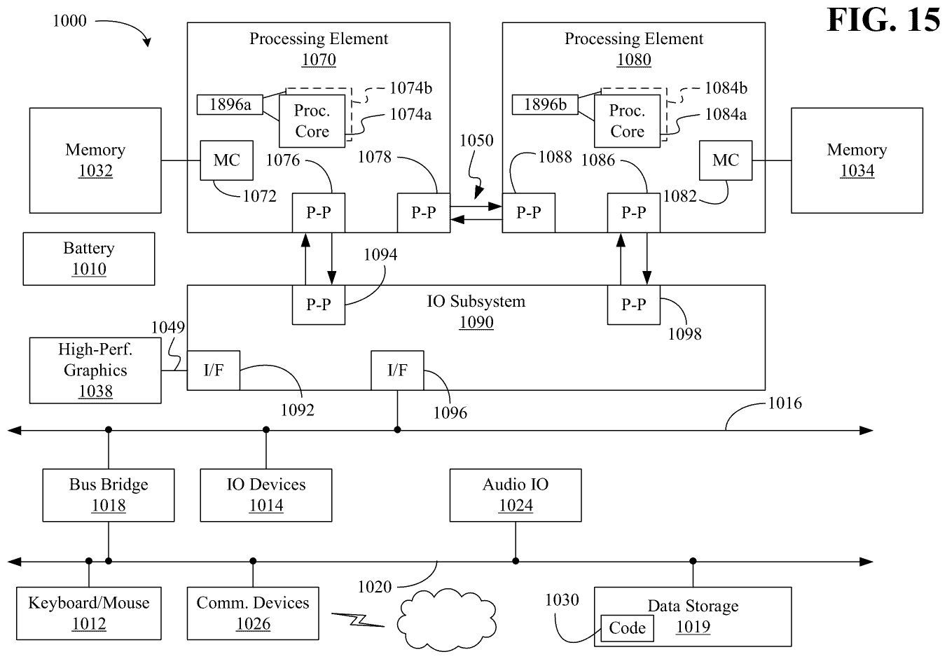

Referring now to FIG. 15, shown is a block diagram of a computing system 1000 embodiment in accordance with an embodiment. Shown in FIG. 15 is a multiprocessor system 1000 that includes a first processing element 1070 and a second processing element 1080. While two processing elements 1070 and 1080 are shown, it is to be understood that an embodiment of the system 1000 may also include only one such processing element.

The system 1000 is illustrated as a point-to-point interconnect system, wherein the first processing element 1070 and the second processing element 1080 are coupled via a point-to-point interconnect 1050. It should be understood that any or all of the interconnects illustrated in FIG. 15 may be implemented as a multi-drop bus rather than point-to-point interconnect.

As shown in FIG. 15, each of processing elements 1070 and 1080 may be multicore processors, including first and second processor cores (i.e., processor cores 1074a and 1074b and processor cores 1084a and 1084b). Such cores 1074a, 1074b, 1084a, 1084b may be configured to execute instruction code in a manner similar to that discussed above in connection with FIG. 14.

Each processing element 1070, 1080 may include at least one shared cache 1896a, 1896b. The shared cache 1896a, 1896b may store data (e.g., instructions) that are utilized by one or more components of the processor, such as the cores 1074a, 1074b and 1084a, 1084b, respectively. For example, the shared cache 1896a, 1896b may locally cache data stored in a memory 1032, 1034 for faster access by components of the processor. In one or more embodiments, the shared cache 1896a, 1896b may include one or more mid-level caches, such as level 2 (L2), level 3 (L3), level 4 (L4), or other levels of cache, a last level cache (LLC), and/or combinations thereof.

While shown with only two processing elements 1070, 1080, it is to be understood that the scope of the embodiments are not so limited. In other embodiments, one or more additional processing elements may be present in a given processor. Alternatively, one or more of processing elements 1070, 1080 may be an element other than a processor, such as an accelerator or a field programmable gate array. For example, additional processing element(s) may include additional processors(s) that are the same as a first processor 1070, additional processor(s) that are heterogeneous or asymmetric to processor a first processor 1070, accelerators (such as, e.g., graphics accelerators or digital signal processing (DSP) units), field programmable gate arrays, or any other processing element. There can be a variety of differences between the processing elements 1070, 1080 in terms of a spectrum of metrics of merit including architectural, micro architectural, thermal, power consumption characteristics, and the like. These differences may effectively manifest themselves as asymmetry and heterogeneity amongst the processing elements 1070, 1080. For at least one embodiment, the various processing elements 1070, 1080 may reside in the same die package.

The first processing element 1070 may further include memory controller logic (MC) 1072 and point-to-point (P-P) interfaces 1076 and 1078. Similarly, the second processing element 1080 may include a MC 1082 and P-P interfaces 1086 and 1088. As shown in FIG. 15, MC's 1072 and 1082 couple the processors to respective memories, namely a memory 1032 and a memory 1034, which may be portions of main memory locally attached to the respective processors. While the MC 1072 and 1082 is illustrated as integrated into the processing elements 1070, 1080, for alternative embodiments the MC logic may be discrete logic outside the processing elements 1070, 1080 rather than integrated therein.

The first processing element 1070 and the second processing element 1080 may be coupled to an I/O subsystem 1090 via P-P interconnects 1076 1086, respectively. As shown in FIG. 15, the I/O subsystem 1090 includes P-P interfaces 1094 and 1098. Furthermore, I/O subsystem 1090 includes an interface 1092 to couple I/O subsystem 1090 with a high performance graphics engine 1038. In one embodiment, bus 1049 may be used to couple the graphics engine 1038 to the I/O subsystem 1090. Alternately, a point-to-point interconnect may couple these components.

In turn, I/O subsystem 1090 may be coupled to a first bus 1016 via an interface 1096. In one embodiment, the first bus 1016 may be a Peripheral Component Interconnect (PCI) bus, or a bus such as a PCI Express bus or another third generation I/O interconnect bus, although the scope of the embodiments are not so limited.

As shown in FIG. 15, various I/O devices 1014 (e.g., biometric scanners, speakers, cameras, sensors) may be coupled to the first bus 1016, along with a bus bridge 1018 which may couple the first bus 1016 to a second bus 1020. In one embodiment, the second bus 1020 may be a low pin count (LPC) bus. Various devices may be coupled to the second bus 1020 including, for example, a keyboard/mouse 1012, communication device(s) 1026, and a data storage unit 1019 such as a disk drive or other mass storage device which may include code 1030, in one embodiment. The illustrated code 1030 may implement the method 50 (FIG. 5), the method 60 (FIG. 6), the method 80 (FIG. 7), the method 110 (FIG. 8), the method 120 (FIG. 9), the method 130 (FIG. 10) and/or the method 140 (FIGS. 11A and 11B), already discussed. Further, an audio I/O 1024 may be coupled to second bus 1020 and a battery 1010 may supply power to the computing system 1000.

Note that other embodiments are contemplated. For example, instead of the point-to-point architecture of FIG. 15, a system may implement a multi-drop bus or another such communication topology. Also, the elements of FIG. 15 may alternatively be partitioned using more or fewer integrated chips than shown in FIG. 15.

### Additional Notes and Examples

Example 1 includes a performance-enhanced computing system comprising a network controller, a processor coupled to the network controller, and a memory coupled to the processor, wherein the memory includes a set of instructions, which when executed by the processor, cause the processor to determine a vocabulary based on one or more of electronic design automation (EDA) tool terminologies or a natural language, query and recommend, by a plurality of virtual agents, actions based on a design state and the vocabulary, wherein the plurality of virtual agents is to include a tool agent and a designer agent, and execute a set of modifications to the design state in accordance with a collaboration between the plurality of virtual agents.
Example 2 includes the computing system of Example 1, wherein the designer agent is trained to query the design state and issue the recommended actions based on the design state.
Example 3 includes the computing system of Example 1, wherein the tool agent is trained to report the design state and issue the recommended actions based on the design state.
Example 4 includes the computing system of any one of Examples 1 to 3, wherein the modifications to the design state result in a single-pass power, performance, area and cost (PPAC) closure.
Example 5 includes at least one computer readable storage medium comprising a set of instructions, which when executed by a computing system, cause the computing system to determine a vocabulary based on one or more of electronic design automation (EDA) tool terminologies or a natural language, query and recommend, by a plurality of virtual agents, actions based on a design state and the vocabulary, wherein the plurality of virtual agents is to include a tool agent and a designer agent, and execute a set of modifications to the design state in accordance with a collaboration between the plurality of virtual agents.
Example 6 includes the at least one computer readable storage medium of Example 5, wherein the designer agent is trained to query the design state and issue the recommended actions based on the design state.
Example 7 includes the at least one computer readable storage medium of Example 5, wherein the tool agent is trained to report the design state and issue the recommended actions based on the design state.
Example 8 includes the at least one computer readable storage medium of any one of Examples 5 to 7, wherein the modifications to the design state result in a single-pass power, performance, area and cost (PPAC) closure.
Example 9 includes at least one computer readable storage medium comprising a set of instructions, which when executed by a computing system, cause the computing system to convert a first user query from a first format to a second format, wherein the first format is incompatible with a trained artificial intelligence (AI) model of a hardware architecture and the second format is compatible with the trained AI model, generate one or more predictions from the trained AI model based on the converted first user query, and select a subset of recommendations from a set of candidate architectures based on the one or more predictions.
Example 10 includes the at least one computer readable storage medium of Example 9, wherein the one or more predictions are generated further based on a second user query, wherein the second user query is in the second format.
Example 11 includes the at least one computer readable storage medium of Example 9, wherein the first format is a text format.
Example 12 includes the at least one computer readable storage medium of Example 9, wherein the first format is a speech format.
Example 13 includes the at least one computer readable storage medium of Example 12, wherein to convert the first user query from the speech format to the second format, the instructions, when executed, further cause the computing system to convert the first user query from the speech format to a text format, and convert the first user query from the text format to the second format.
Example 14 includes the at least one computer readable storage medium of Example 13, wherein the instructions, when executed, further cause the computing system to generate a correction prompt based on the first user query in the text format, and modify the first user query in the text format based on a response to the correction prompt.
Example 15 includes the at least one computer readable storage medium of any one of Examples 9 to 14, wherein the instructions, when executed, further cause the computing system to conduct a baseline training of the AI model based on the set of candidate architectures.
Example 16 includes the at least one computer readable storage medium of Example 15, wherein the baseline training is conducted based on one or more of hardware emulation measurements, architectural simulation results or a plurality of different workloads.
Example 17 includes the at least one computer readable storage medium of Example 15, wherein the instructions, when executed, further cause the computing system to conduct a continual learning training of the AI model after the baseline training based on the subset of recommendations.
Example 18 includes the at least one computer readable storage medium of Example 17, wherein the continual learning training is conducted further based on hardware emulation measurements associated with the subset of recommendations.
Example 19 includes the at least one computer readable storage medium of Example 17, wherein the continual learning training is conducted further based on architectural simulation results associated with the subset of recommendations.
Example 20 includes the at least one computer readable storage medium of Example 17, wherein the continual learning training is conducted further based on a plurality of different workloads associated with the subset of recommendations.
Example 21 includes a method of operating a performance-enhanced computing system, the method comprising determining a vocabulary based on one or more of electronic design automation (EDA) tool terminologies or a natural language, querying and recommending, by a plurality of virtual agents, actions based on a design state and the vocabulary, wherein the plurality of virtual agents is to include a tool agent and a designer agent, and executing a set of modifications to the design state in accordance with a collaboration between the plurality of virtual agents.
Example 22 includes a method of operating a performance-enhanced computing system, the method comprising converting a first user query from a first format to a second format, wherein the first format is incompatible with a trained artificial intelligence (AI) model of a hardware architecture and the second format is compatible with the trained AI model, generating one or more predictions from the trained AI model based on the converted first user query, and selecting a subset of recommendations from a set of candidate architectures based on the one or more predictions.
Example 23 includes an apparatus comprising means for performing the method of any one of Examples 21 to 22.

Embodiments may be implemented in one or more modules as a set of logic instructions stored in a machine- or computer-readable storage medium such as random access memory (RAM), read only memory (ROM), programmable ROM (PROM), firmware, flash memory, etc., in hardware, or any combination thereof. For example, hardware implementations may include configurable logic, fixed-functionality logic, or any combination thereof. Examples of configurable logic (e.g., configurable hardware) include suitably configured programmable logic arrays (PLAs), field programmable gate arrays (FPGAs), complex programmable logic devices (CPLDs), and general purpose microprocessors. Examples of fixed-functionality logic (e.g., fixed-functionality hardware) include suitably configured application specific integrated circuits (ASICs), combinational logic circuits, and sequential logic circuits. The configurable or fixed-functionality logic can be implemented with complementary metal oxide semiconductor (CMOS) logic circuits, transistor-transistor logic (TTL) logic circuits, or other circuits.

Example sizes/models/values/ranges may have been given, although embodiments are not limited to the same. As manufacturing techniques (e.g., photolithography) mature over time, it is expected that devices of smaller size could be manufactured. In addition, well known power/ground connections to IC chips and other components may or may not be shown within the figures, for simplicity of illustration and discussion, and so as not to obscure certain aspects of the embodiments. Further, arrangements may be shown in block diagram form in order to avoid obscuring embodiments, and also in view of the fact that specifics with respect to implementation of such block diagram arrangements are highly dependent upon the computing system within which the embodiment is to be implemented, i.e., such specifics should be well within purview of one skilled in the art. Where specific details (e.g., circuits) are set forth in order to describe example embodiments, it should be apparent to one skilled in the art that embodiments can be practiced without, or with variation of, these specific details. The description is thus to be regarded as illustrative instead of limiting.

The term “coupled” may be used herein to refer to any type of relationship, direct or indirect, between the components in question, and may apply to electrical, mechanical, fluid, optical, electromagnetic, electromechanical or other connections. In addition, the terms “first”, “second”, etc. may be used herein only to facilitate discussion, and carry no particular temporal or chronological significance unless otherwise indicated.

As used in this application and in the claims, a list of items joined by the term “one or more of” may mean any combination of the listed terms. For example, the phrases “one or more of A, B or C” may mean A; B; C; A and B; A and C; B and C; or A, B and C.

Those skilled in the art will appreciate from the foregoing description that the broad techniques of the embodiments can be implemented in a variety of forms. Therefore, while the embodiments have been described in connection with particular examples thereof, the true scope of the embodiments should not be so limited since other modifications will become apparent to the skilled practitioner upon a study of the drawings, specification, and following claims.

We claim:

1. A computing system comprising:
a network controller;
a processor coupled to the network controller; and
a memory coupled to the processor, wherein the memory includes a set of instructions, which when executed by the processor, cause the processor to:
determine a vocabulary based on one or more of electronic design automation (EDA) tool terminologies or a natural language,
query and recommend, by a plurality of virtual agents, actions based on a design state and the vocabulary, wherein the plurality of virtual agents is to include a tool agent and a designer agent, and
execute a set of modifications to the design state in accordance with a collaboration between the plurality of virtual agents.

2. The computing system of claim 1, wherein the designer agent is trained to query the design state and issue the recommended actions based on the design state.

3. The computing system of claim 1, wherein the tool agent is trained to report the design state and issue the recommended actions based on the design state.

4. The computing system of claim 1, wherein the modifications to the design state result in a single-pass power, performance, area and cost (PPAC) closure.

5. At least one computer readable storage medium comprising a set of instructions, which when executed by a computing system, cause the computing system to:
determine a vocabulary based on one or more of electronic design automation (EDA) tool terminologies or a natural language;
query and recommend, by a plurality of virtual agents, actions based on a design state and the vocabulary, wherein the plurality of virtual agents is to include a tool agent and a designer agent; and
execute a set of modifications to the design state in accordance with a collaboration between the plurality of virtual agents.

6. The at least one computer readable storage medium of claim 5, wherein the designer agent is trained to query the design state and issue the recommended actions based on the design state.

7. The at least one computer readable storage medium of claim 5, wherein the tool agent is trained to report the design state and issue the recommended actions based on the design state.

8. The at least one computer readable storage medium of claim 5, wherein the modifications to the design state result in a single-pass power, performance, area and cost (PPAC) closure.

9. At least one computer readable storage medium comprising a set of instructions, which when executed by a computing system, cause the computing system to:
convert a first user query from a first format to a second format, wherein the first format is incompatible with a trained artificial intelligence (AI) model of a hardware architecture and the second format is compatible with the trained AI model;
generate one or more predictions from the trained AI model based on the converted first user query; and
select a subset of recommendations from a set of candidate architectures based on the one or more predictions.

10. The at least one computer readable storage medium of claim 9, wherein the one or more predictions are generated further based on a second user query, wherein the second user query is in the second format.

11. The at least one computer readable storage medium of claim 9, wherein the first format is a text format.

12. The at least one computer readable storage medium of claim 9, wherein the first format is a speech format.

13. The at least one computer readable storage medium of claim 12, wherein to convert the first user query from the speech format to the second format, the instructions, when executed, further cause the computing system to:
convert the first user query from the speech format to a text format; and
convert the first user query from the text format to the second format.

14. The at least one computer readable storage medium of claim 13, wherein the instructions, when executed, further cause the computing system to:
generate a correction prompt based on the first user query in the text format; and
modify the first user query in the text format based on a response to the correction prompt.

15. The at least one computer readable storage medium of claim 9, wherein the instructions, when executed, further cause the computing system to conduct a baseline training of the AI model based on the set of candidate architectures.

16. The at least one computer readable storage medium of claim 15, wherein the baseline training is conducted based on one or more of hardware emulation measurements, architectural simulation results or a plurality of different workloads.

17. The at least one computer readable storage medium of claim 15, wherein the instructions, when executed, further cause the computing system to conduct a continual learning training of the AI model after the baseline training based on the subset of recommendations.

18. The at least one computer readable storage medium of claim 17, wherein the continual learning training is conducted further based on hardware emulation measurements associated with the subset of recommendations.

19. The at least one computer readable storage medium of claim 17, wherein the continual learning training is conducted further based on architectural simulation results associated with the subset of recommendations.

20. The at least one computer readable storage medium of claim 17, wherein the continual learning training is conducted further based on a plurality of different workloads associated with the subset of recommendations.
